(19) United States
(12) Patent Application Publication
(10) Pub. No.: US 2017/0026032 A9
(43) Pub. Date: Jan. 26, 2017

(54) OFFSET CANCELLING CIRCUIT AND METHOD

(71) Applicant: Semiconductor Components Industries, LLC, Phoenix, AZ (US)

(72) Inventor: Takashi Ogawa, Ogaki-shi (JP)

(73) Assignee: Semiconductor Components Industries, LLC, Phoenix, AZ (US)

(21) Appl. No.: 14/206,857

(22) Filed: Mar. 12, 2014

Related U.S. Application Data
(63) Continuation of application No. 12/796,167, filed on Jun. 8, 2010, now abandoned.

(30) Foreign Application Priority Data
Jun. 8, 2009 (JP) 2009-136906

(51) Int. Cl. H03K 5/003

(52) U.S. Cl. CPC H03K 5/003

(57) ABSTRACT

When a voltage is applied from outside such that a current flowing in a Hall element is switched, each of a plurality of capacitors is charged with an output voltage of the Hall element in each state. A dummy switching element is connected to a switching element which connects the plurality of capacitors in parallel to each other, the dummy switching element and the switching element being controlled to be switched ON and OFF exclusively with respect to each other.

### CROSS-REFERENCE TO RELATED APPLICATIONS

The entire disclosure of Japanese Patent Application No. 2009-136906 filed on Jun. 8, 2009, including specification, claims, drawings, and abstract is incorporated herein by reference in its entirety.

### BACKGROUND

1. Technical Field

The present invention relates to an offset cancelling circuit which is used for adjustment of an output or the like of a Hall element.

2. Related Art

In recent years, image capturing devices such as a digital still camera and a digital video camera realize higher image quality by increasing the number of pixels of an image capturing element of the image capturing device. On the other hand, as another method for realizing higher image quality of the image capturing device, it is desired to equip the image capturing device with a vibration absorption control circuit having a shake correction function in order to prevent shaking of an imaging target caused by shaking of the hand holding the image capturing device.

A vibration absorption control circuit for shake correction receives a signal from a gyro sensor which detects an angular velocity component generated by vibration of the image capturing device, and drives optical components such as a lens and an image capturing element according to the received signal, to prevent shaking of the imaging target. With such a configuration, even if the image capturing device vibrates, the component of the vibration is not reflected in the obtained image signal, and a high-quality image signal having no image shaking can be obtained.

In this process, a Hall element is used for detecting a position of the optical component such as the lens which is driven. As shown in FIG. 11, an equivalent circuit of the Hall element can be represented as a bridge circuit of resistors R1˜R4. An output signal of the Hall element therefore includes an offset component due to influences of variations in the resistors, according to a combination of a terminal on which a power supply voltage Vcc is applied and a terminal from which the output signal is extracted.

Because of this, as shown in FIG. 12, an offset cancelling circuit 100 comprising a Hall element 10, an amplifier circuit 12, and an averaging circuit 14 is used. In the offset cancelling circuit 100, switching elements S1˜S19 are controlled to be switched ON and OFF to apply voltages such that currents flowing in the Hall element 10 differ by 90°, capacitors C1 and C2 are charged in each state, and the charged voltages of the capacitors C1 and C2 are added and averaged. When the current flowing in the Hall element 10 is changed by 90°, the offset of the output voltage of the Hall element 10 occurs in an opposite direction, and thus the offset value of the output voltage of the Hall element 10 is cancelled.

With the provision of the offset cancelling circuit, the offset value of the output voltage of the Hall element can be cancelled.

For the switching elements S1˜S19, MOS transistors are used. The MOS transistor takes advantage of a characteristic that the transistor is switched OFF when a gate-source voltage is less than a threshold voltage and the transistor is switched ON when the gate-source voltage is greater than or equal to the threshold voltage. When the MOS transistor is to be switched OFF, a gate voltage is reduced from the power supply voltage to a voltage less than the threshold voltage. An overlap capacitance exists between the gate and the source and between the gate and the source, and the charge in the channel of the MOS transistor are absorbed by the source and the drain when the transistor is switched OFF. Because of this, when the MOS transistor is switched OFF, a part of an amount of charge calculated as a product of an amount of change of the voltage of the gate and the overlap capacity and an amount of charge stored in the channel would change. This is known as charge injection (noise) of the switching element.

In the offset cancelling circuit 100 also due to the charge injection noise of the switching elements S1˜S19, noise may be superposed on the output voltage from the Hall element, which may be problematic.

Therefore, a technique is desired which reduces the influence of the charge injection noise in the offset cancelling circuit.

### SUMMARY

According to one aspect of the present invention, there is provided an offset cancelling circuit of a Hall element, comprising a plurality of capacitors, a group of first switching elements to which a voltage is applied from outside such that a current flowing in the Hall element is switched and which are controlled to be switched ON and OFF such that an output voltage of the Hall element is applied to one of the plurality of capacitors in each state, and a group of second switching elements which are controlled to be switched ON and OFF such that an output voltage corresponding to charge which is charged in the plurality of capacitors is output in a state where the plurality of capacitors are connected in parallel to each other, wherein a dummy switching element is connected to at least a part of the group of the second switching elements in such a manner that the dummy switching element and the part of the group of the second switching element are controlled to be switched ON and OFF exclusively with respect to each other.

### BRIEF DESCRIPTION OF THE DRAWINGS

A preferred embodiment of the present invention will be described i n further detail based on the following drawings, wherein:

FIG. 1 is a diagram showing a structure of an offset cancelling circuit according to a preferred embodiment of the present invention;

FIG. 2 is a diagram showing an action of the offset cancelling circuit according to a preferred embodiment of the present invention;

FIG. 3 is a diagram showing an action of the offset cancelling circuit according to a preferred embodiment of the present invention;

FIG. 4 is a diagram showing an action of the offset cancelling circuit according to a preferred embodiment of the present invention;

FIGS. 5A and 5B are diagrams for explaining an action of a dummy switching element of the offset cancelling circuit according to a preferred embodiment of the present invention;

FIGS. 6A and 6B are diagrams for explaining an action of the dummy switching element of the offset cancelling circuit according to a preferred embodiment of the present invention;

FIG. 7 is a diagram showing an action of the dummy switching element in the offset cancelling circuit;

FIG. 8 is a diagram showing a structure of a capacitor which is used in the offset cancelling circuit according to a preferred embodiment of the present invention;

FIG. 9 is a diagram showing an equivalent circuit of the capacitor which is used in the offset cancelling circuit according to a preferred embodiment of the present invention;

FIGS. 10A and 10B are diagrams showing an action of the capacitor which is used in the offset cancelling circuit according to a preferred embodiment of the present invention;

FIG. 11 is a diagram showing an equivalent circuit of a Hall element; and

FIG. 12 is a diagram showing a structure of an offset cancelling circuit in related art.

### DETAILED DESCRIPTION

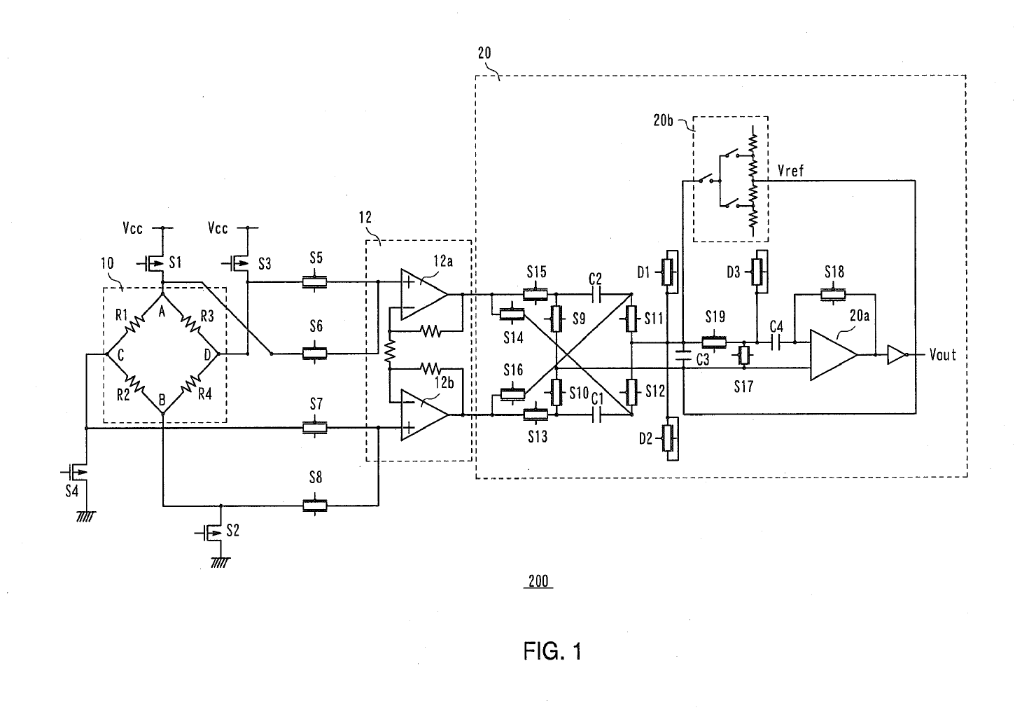

FIG. 1 shows a basic structure of an offset cancelling circuit 200 of a Hall element. The offset cancelling circuit 200 of the Hall element comprises a Hall element 10, an amplifier circuit 12, and an averaging circuit 20.

The Hall element 10 can be represented as a bridge circuit of resistors R1˜R4. Switching elements S1˜S8 which switch connection points A˜D of the resistors R1˜R4 to a power supply voltage Vcc, ground, or output are connected to the resistors R1˜R4.

The amplifier circuit 12 comprises operational amplifiers 12a and 12b. The operational amplifier 12a amplifies a voltage which is input to a non-inverting input terminal (+) and outputs the amplified voltage. The operational amplifier 12b amplifies a voltage which is input to a non-inverting input terminal (+) and outputs the amplified voltage.

The averaging circuit 20 comprises switching elements S9˜S19, dummy switching elements D1˜D3, capacitors C1˜C4, an operational amplifier 20a, and a reference voltage generating circuit 20b.

The switching elements S9˜S19 connect any of output terminals of the operational amplifiers 12a and 12b, terminals of the capacitors C1˜C4, and an input terminal of the operational amplifier 20a with each other. The switching elements S9˜S12 and S19 are controlled to be switched ON and OFF such that an output voltage corresponding to charge which is charged in the capacitors C1 and C2 is output in a state where the capacitors C1 and C2 are connected in parallel. In other words, the switching elements S9˜S12 and S19 are controlled to be switched ON and OFF such that the capacitors C1 and C2 are connected in parallel with each other and connected to a capacitor C3 for output, and a terminal voltage of the capacitor C3 is input to the operational amplifier 20a. The switching elements S13˜S16 are controlled to be switched ON and OFF such that when a voltage is applied from the outside to switch the current flowing in the Hall element 10, the output voltage of the Hall element 10 is applied to one of the capacitors C1 and C2 in each state. In other words, with the switching elements S13˜S16 controlled to be switched ON and OFF, one of the capacitors C1 and C2 is charged by the output voltage of the Hall element 10. The switching element S17 is used for discharging the charges which are charged in the capacitor C3. The switching element S18 is used for connecting an input terminal and an output terminal of the operational amplifier 20a. The switching elements S9˜S19 preferably have approximately the same degree of element capacitance regardless of whether they are P type or N type.

The dummy switching element is a switching element which is controlled to be switched ON and OFF exclusively with respect to the switching element to which the dummy switching element is connected. The dummy switching element may have a structure wherein the input terminal and the output terminal of the switching element are connected. The input terminal and the output terminal of the dummy switching element which are connected to each other are connected to an input terminal or an output terminal of the switching element to which the dummy switching element is connected. The dummy switching element preferably has an element capacity of approximately ½ of the switching element to which the dummy switching element is connected.

In the present embodiment, the dummy switching elements D1˜D3 are switched OFF when the switching elements S11, S12, and S19 are switched ON, respectively, and are switched ON when the switching elements S11, S12, and S19 are switched OFF, respectively. In other words, the dummy switching elements D1˜D3 are connected to the switching elements S11, S12, and S19 which are a connection destination. The dummy switching elements D1˜D3 have element capacities of approximately ½ of the switching elements S11, S12, and S19, respectively.

An operation of the offset cancelling circuit 200 will now be described. The offset cancelling circuit 200 cancels the offset value of the output voltage of the Hall element 10 and outputs the resulting voltage by switching among a first state, a second state, and an output state, which will be described below.

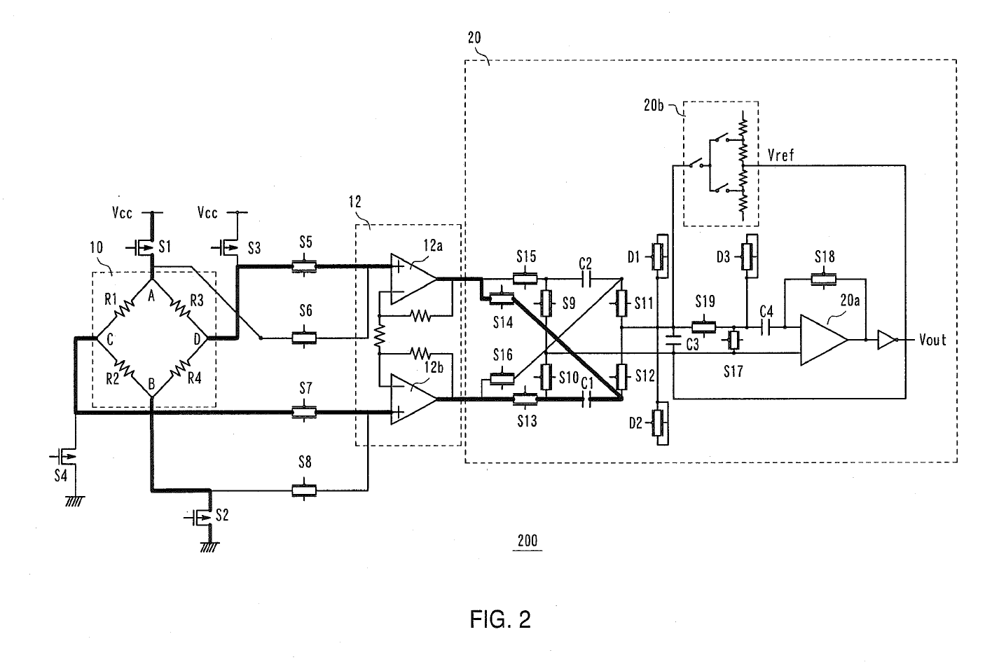

First, as shown in FIG. 2, the switching elements S1˜S19 and the dummy switching elements D1˜D3 are controlled to be switched ON and OFF, to set the offset cancelling circuit 200 into a first state. The switching element S1 is switched ON and the switching element S6 is switched OFF to apply a power supply voltage Vcc to the connection point A of the resistors R1 and R3, the switching element S2 is switched ON and the switching element S8 is switched OFF to connect the connection point B of the resistors R2 and R4 to ground, the switching element S7 is switched ON and the switching element S4 is switched OFF to connect the connection point C of the resistors R1 and R2 to the non-inverting input terminal (+) of the operational amplifier 12b, and the switching element S5 is switched ON and the switching element S3 is switched OFF to connect the connection point D of the resistors R3 and R4 to the non-inverting input terminal (+) of the operational amplifier 12a . In addition, of the switching elements S9˜S19, the switching elements S14 and S16 are switched ON and the other switching elements are switched OFF to connect the output of the operational amplifier 12a to a positive terminal of the capacitor C1 and the output of the operational amplifier 12b to a negative terminal of the capacitor C1, so as to achieve a state where the capacitor C1 is charged by the output voltages of the operational amplifiers 12a and 12b. This state is referred to as the first state.

In this state, as the switching elements S11, S12, and S19 are in the OFF state, the dummy switching elements D1˜D3 are set to the ON state.

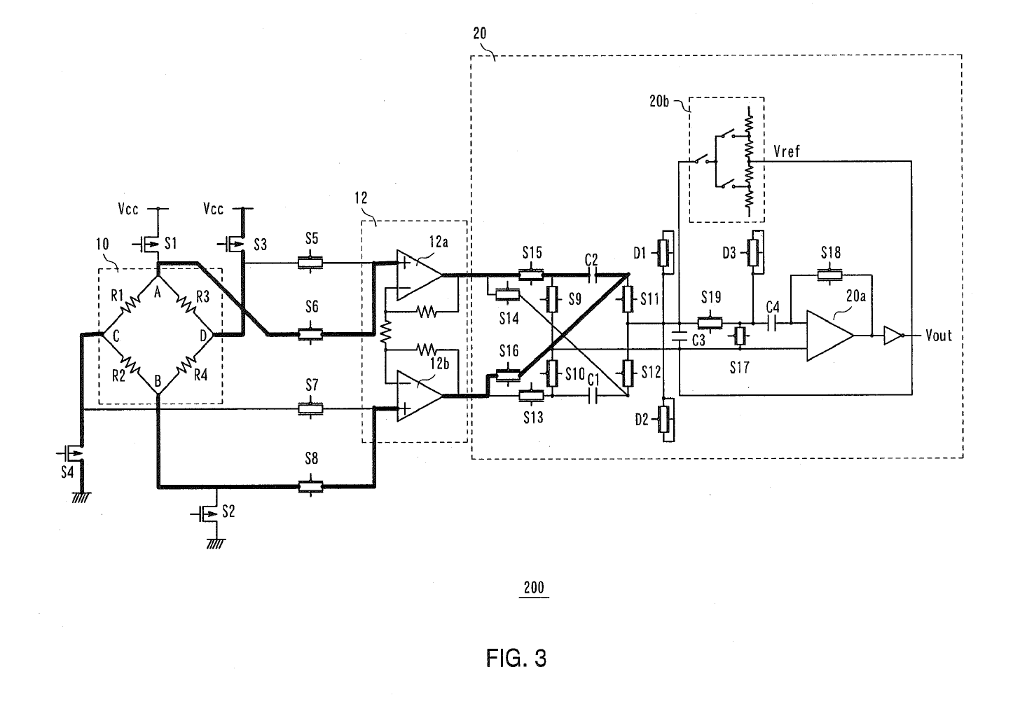

Next, as shown in FIG. 3, the switching elements S1˜S19 and the dummy switching elements D1˜D3 are controlled to be switched ON and OFF, to set the offset cancelling circuit 200 in a second state. The switching element S6 is switched ON and the switching element S1 is switched OFF to connect the connection point A of the resistors R1 and R3 to the non-inverting input terminal (+) of the operational amplifier 12a , the switching element S8 is switched ON and the switching element S2 is switched OFF to connect the connection point B of the resistors R2 and R4 to the non-inverting input terminal (+) of the operational amplifier 12b, the switching element S4 is switched ON and the switching element S7 is switched OFF to connect the connection point C of the resistors R1 and R2 to the ground, and the switching element S3 is switched ON and the switching element S5 is switched OFF to apply the power supply voltage Vcc to the connection point D of the resistors R3 and R4. In addition, of the switching elements S9˜S19, the switching elements S15 and S16 are switched ON and the other switching elements are switched OFF, to connect the output of the operational amplifier 12a to a negative terminal of the capacitor C2 and the output of the operational amplifier 12b to a positive terminal of the capacitor C2, so as to achieve a state where the capacitor C2 is charged by the output voltages of the operational amplifiers 12a and 12b. This state is referred to as the second state.

In this state, as the switching elements S11, S12, and S19 are in the OFF state, the dummy switching elements D1˜D3 are set to the ON state.

In this manner, voltages are applied to change the direction of the current flowing in the Hall element 10, to switch between the first and second states, and the capacitors C1 and C2 are respectively charged with the Hall voltages V1 and V2 of two directions) (90°) for the four terminals of the Hall element 10.

The charged voltage V1 is a voltage in which an offset voltage Voff is added to the Hall voltage Vhall in the first state. That is, the charged voltage V1=Vhall+Voff. When the current flowing in the Hall element 10 is changed by 90°, the offset voltage Voff of the Hall element 10 is generated in the opposite direction. Therefore, the charged voltage V2 is a voltage in which the offset voltage Voff is subtracted from the Hall voltage Vhall at the second state. That is, the charged voltage V2=Vhall−Voff.

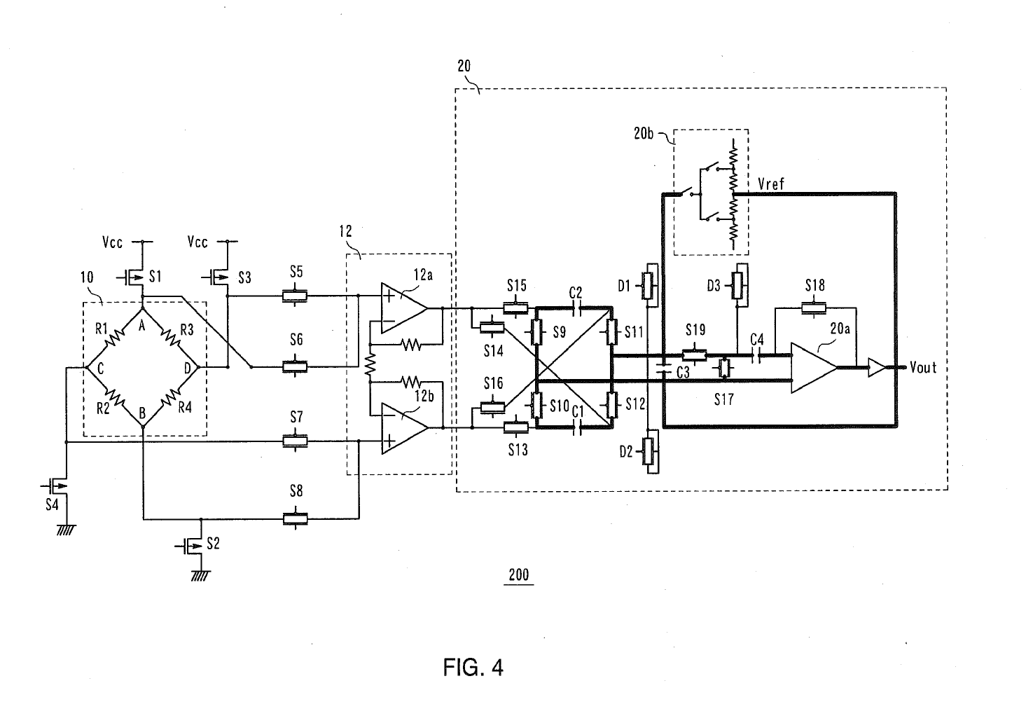

As shown in FIG. 4, in an output state, the switching elements S13˜S16 are switched OFF, and the operational amplifiers 12a and 12b and the capacitors C1 and C2 are disconnected. The switching elements S11, S12, and S19 are switched ON, and the switching element S18 is switched OFF, to commonly connect the positive terminals of the capacitors C1 and C2 to one of the input terminals of the operational amplifier 20a via a capacitor C4. The switching elements S9 and S10 are switched ON, to commonly connect the negative terminals of the capacitors C1 and C2 to the other one of the input terminals of the operational amplifier 20a. The other terminal of the operational amplifier 20a is set to Vref generated by the reference voltage generating circuit 20b. The switching element S17 for deleting charge of the capacitor C3 is also set to the OFF state.

In this state, as the switching elements S11, S12, and S19 are in the ON state, the dummy switching elements D1˜D3 are set in the OFF state.

By the offset cancelling circuit 200 being set in the output state, the capacitors C1 and C2 are connected in parallel to each other, charge stored in the capacitors C1 and C2 is re-distributed to the capacitors C1, C2, and C3, and the charged voltages V1 and V2 are averaged. In this manner, the offset value of the output voltage of the Hall element 10 is cancelled, and a voltage is output as the output voltage Vout.

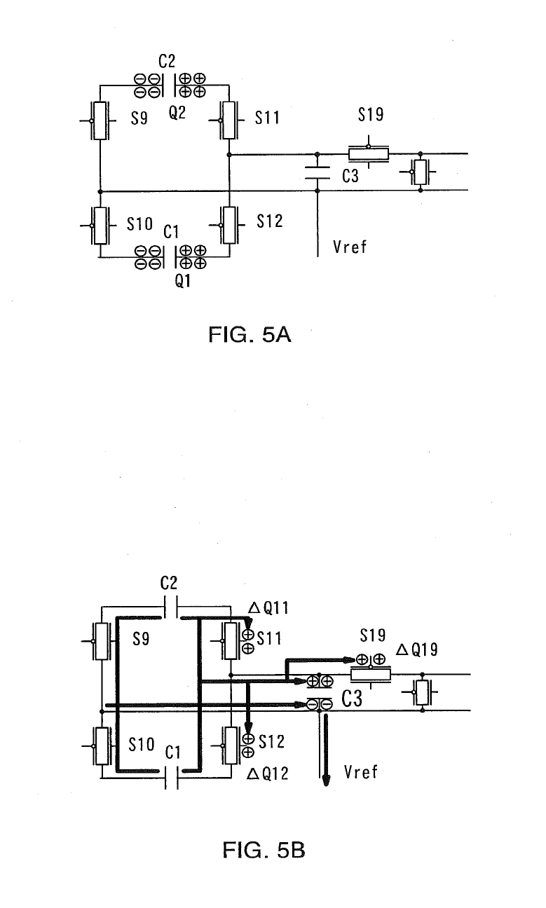

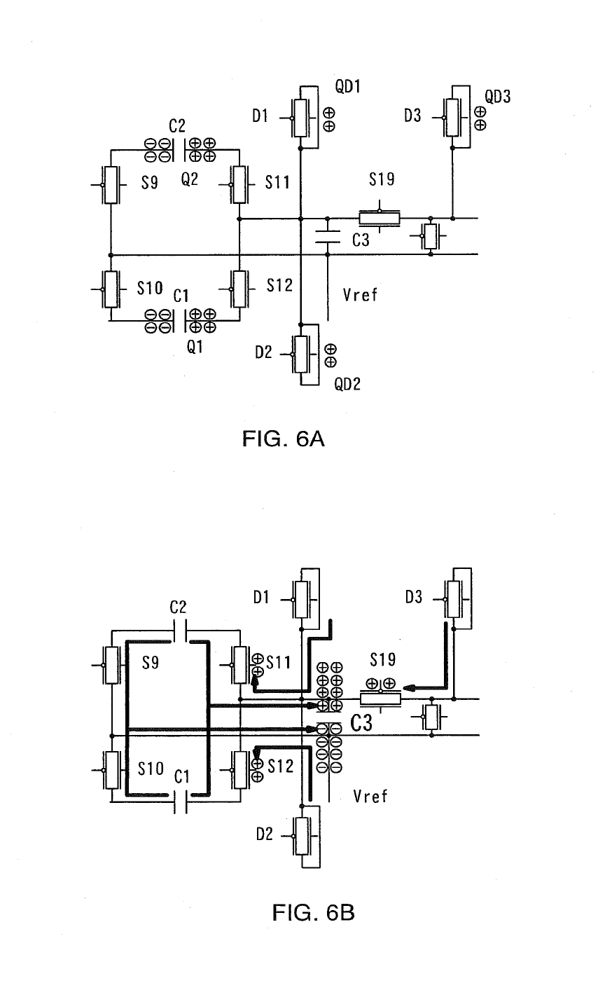

The operation of the dummy switching elements D1˜D3 will now be described with reference to FIGS. 5A, 5B, 6A, and 6B. FIGS. 5A, 5B, 6A, and 6B schematically show the movement of the charge when the state is switched from the state where the switching of the first state and the second state is completed and charge is stored in the capacitors C1 and C2, to the output state.

In a structure where the dummy switching elements D1˜D3 are not provided, as shown in FIG. 5A, when the switching elements S11, S12, and S19 are in the OFF state, the capacitors C1 and C2 are charged to the voltages V1 and V2, respectively. In this process, the capacitor C1 stores charge Q1=V1/C1 and the capacitor C2 stores charge Q2=V2/C2.

When the switching elements S11, S12, and S19 are switched ON, as shown in FIG. 5B, the positive terminals of the capacitors C1 and 02 and the positive terminal of the capacitor C3 are connected, and a part of the charges Q1 and Q2, that is ΔQ11, ΔQ12, and ΔQ19, is sucked into the channels of the switching elements S11, S12, and S19. As a result, the charge Q1+Q2−ΔQ11−ΔQ12−ΔQ19 is re-distributed to the capacitors C1˜C3. The charge ΔQ11+ΔQ12+ΔQ19 acts as the channel injection noise which reduces the output voltage Vout.

In the structure where the dummy switching elements D1˜D3 are provided, as shown in FIG. 6A, when the switching elements S11, S12, and S19 are in the OFF state, the capacitors C1 and C2 are charged to the voltages V1 and V2, respectively, and the channels of the dummy switching elements D1˜D3 are charged with charges QD1, QD2, and QD3, respectively.

When the switching elements S11, S12, and S19 are switched ON, the dummy switching elements D1˜D3 are switched OFF, and, as shown in FIG. 6B, the positive terminals of the capacitors C1 and C2 and the positive terminal of the capacitor C3 are connected. In this process, by adjusting the element capacities of the switching elements S11, S12, and S19 and the element capacities of the dummy switching elements D1˜D3 in advance, it is possible to compensate for the charges sucked into the channels of the switching elements S11, S12, and S19 by the charges QD1, QD2, and QD3. As a result, the charges Q1+Q2 are accurately re-distributed to the capacitors C1˜C3, and the output voltage Vout would more accurately indicate the Hall voltage.

More specifically, the element capacitance of the dummy switching elements D1˜D3 are preferably set to about 0.5 times to 1.5 times the element capacities of the switching elements S11, S12, and S19.

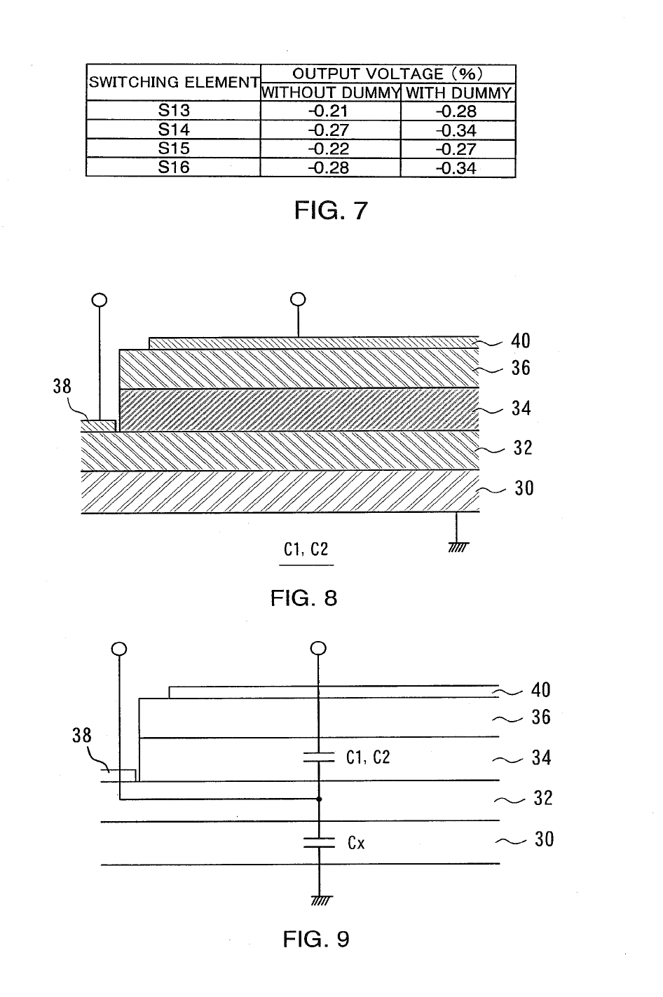

FIG. 7 shows a result of a simulation for a relationship with the output voltage Vout when the dummy switching elements are provided for the switching elements S13˜S16. FIG. 7 shows a percentage of a difference with respect to an ideal value of the output voltage Vout between a case where no dummy switching element is provided and a case where the dummy switching elements are provided. In FIG. 7, a minus sign indicates that the simulation result is lower than the ideal value. As shown in FIG. 7, even if the dummy switching elements are connected for the switching elements S13˜S16, the output voltage Vout would be further reduced, and the reduction effect of the charge injection noise on the output voltage Vout is not significant.

A reason for this is believed to be that, in the structure where the dummy switching elements are connected to the switching elements S13˜S16, after the capacitors C1 and C2 are charged in the first state or the second state, and the switching elements S13˜S16 are switched OFF and the dummy switching elements are switched ON, a part of the charges stored in the capacitors C1 and C2 are sucked by the dummy switching elements.

Therefore, it is preferable to not connect the dummy switching elements to the switching element S13˜S16. That is, in the offset cancelling circuit 200, it is preferable to not connect a dummy switching element to a switching element which is controlled to be switched ON and OFF when a voltage is applied from the outside to switch the current flowing in the Hall element 10 such that the output voltage of the Hall element 10 is applied to one of the capacitors C1 and C2 in each state, and which is used for connecting the output terminals of the operational amplifiers 12a and 12b to the capacitors C1 and C2 in the first state and the second state.

In addition, because the switching elements S9 and S10 are in a low-impedance state after the output state, even if dummy switching elements are connected to the switching elements S9 and S10, the reduction effect of the charge injection noise with respect to the output voltage Vout is not significant. Therefore, it is preferable to not connect the dummy switching elements to the switching elements S9 and S10.

FIG. 8 shows an example element structure of the capacitors C1 and C2 in the offset cancelling circuit 200.

The capacitors C1 and C2 are formed by layering a polysilicon layer 32, an insulating layer 34, and a polysilicon layer 36 over a semiconductor substrate 30. An electrode 38 is formed on a surface of the polysilicon layer 32 in an opening formed by patterning the insulating layer 34 and the polysilicon layer 36. The insulating layer 34 is formed by layering over the polysilicon layer 32, and the polysilicon layer 36 is formed by layering over the insulating layer 34. An electrode 40 is formed on a surface of the polysilicon layer 36. Output terminals are provided to extend from the electrode 38 and the electrode 40.

The capacitors C1 and 02 having such a structure take advantage of the capacitances between the semiconductor substrate 30 and the electrode 38 and between the semiconductor substrate 30 and the electrode 40 while the semiconductor substrate 30 is grounded. FIG. 9 shows an equivalent circuit of the capacitors C1 and C2. As shown in FIG. 9, a parasitic capacitance Cx formed on the semiconductor substrate 30 is connected to the capacitors C1 and C2.

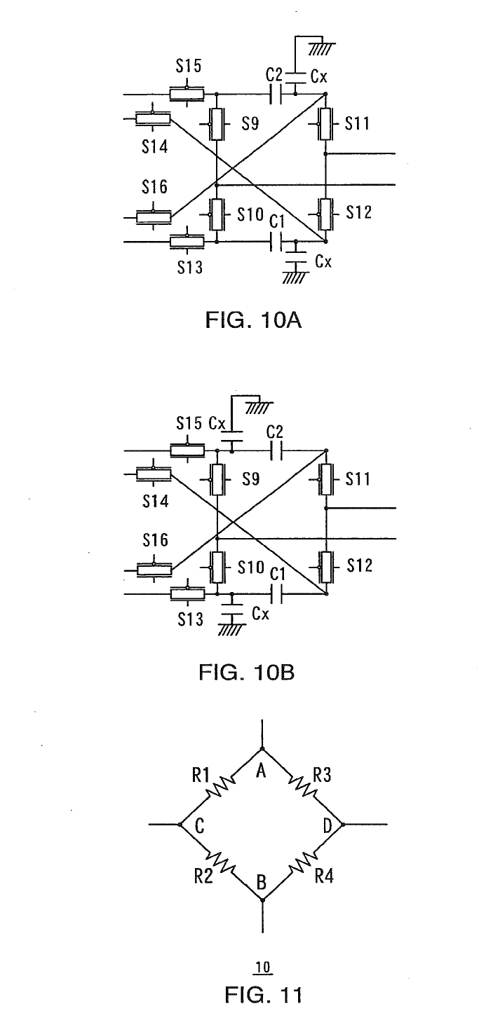

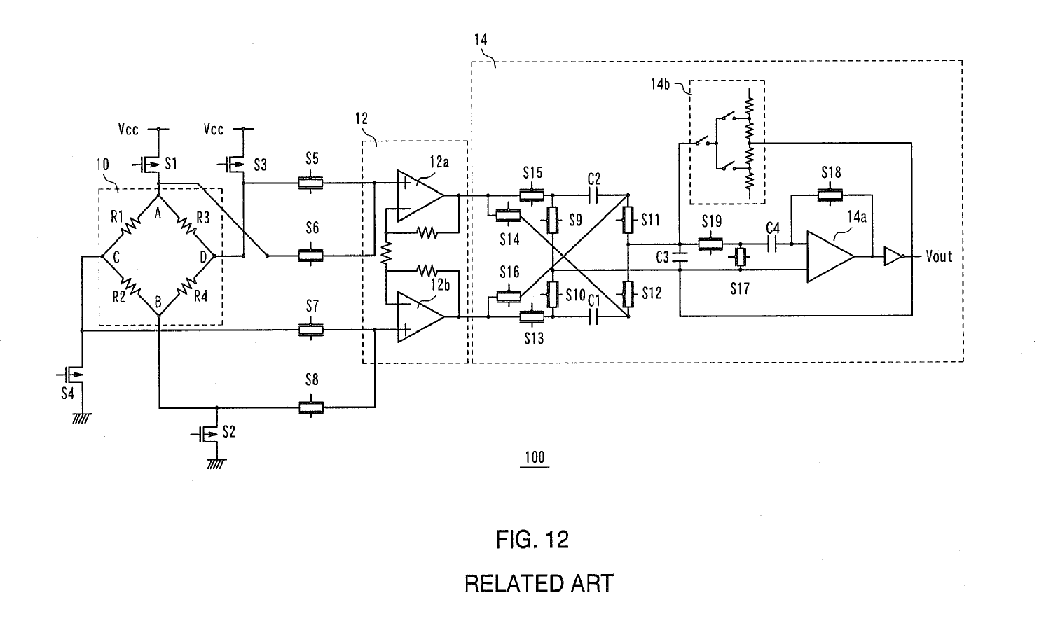

When the capacitors C1 and C2 having such a structure are used, as shown in FIG. 10A, if the capacitors C1 and C2 are connected to the operational amplifiers 12a and 12b such that the parasitic capacitance Cx is placed on the side of the positive terminals of the capacitors C1 and C2 of the offset cancelling circuit 200, when the charges stored in the capacitors C1 and C2 are to be re-distributed to the capacitors C1, C2, and C3 in the output state, the charges are re-distributed to the capacitors C1, C2, and C3 in the floating state and also to the parasitic capacitance Cx.

If, on the other hand, as shown in FIG. 10B, the capacitors C1 and C2 are connected to the operational amplifiers 12a and 12b such that the parasitic capacitance Cx is placed on the side of the negative terminals of the capacitors C1 and C2 of the offset cancelling circuit 200, when the charges stored in the capacitors C1 and C2 are to be re-distributed to the capacitors C1, C2, and C3 in the output state, the negative terminals of the capacitors C1 and C2 and the terminal of the parasitic capacitance Cx are set to the reference voltage Vref. Charge corresponding to the reference voltage Vref is supplied from the reference voltage generating circuit 20b or the like to the parasitic capacitance Cx, and the charges stored in the capacitors C1 and C2 are accurately re-distributed to the capacitors C1, C2, and C3. As a result, the output voltage Vout is set closer to the correct Hall voltage.

A difference in the reference voltage is caused between the time when the capacitors C1 and C2 are charged and the time when the charges are re-distributed to the capacitors C1, C2, and C3. The difference in the reference voltage is a difference between a center voltage of the Hall element 10 and the reference voltage of the reference voltage generating circuit 20b used in the operational amplifier 20a. In addition to this voltage difference, the influence of the charge due to the parasitic capacitance would cause the offset during comparison at the operational amplifier 20a. By placing the parasitic capacitance Cx in a manner as shown in FIG. 10B, the influence of the offset during comparison at the operational amplifier 20a can be reduced.

As described, according to the present embodiment, the offset voltage of the output voltage of the Hall element can be cancelled and the influence of the charge injection noise on the offset cancelling circuit can be reduced.

1. (canceled)

2. (canceled)

3. (canceled)

4. (canceled)

5. (canceled)

6. (canceled)

7. (canceled)

8. (canceled)

9. An offset cancellation circuit, comprising:
a first switching network having a plurality of inputs and first and second outputs;
a second switching network having first and second inputs, first and second outputs, and a plurality of connection nodes, the first input of the second switching network coupled to the first output of the first switching network;
a first capacitor having first and second terminals, the first terminal of the first capacitor coupled to a first connection node of the plurality of connection nodes and the second terminal of the first capacitor coupled to a second connection node of the plurality of connection nodes;
a second capacitor having first and second terminals, the first terminal of the second capacitor coupled to a third connection node of the plurality of connection nodes and the second terminal of the second capacitor coupled to a fourth connection node of the plurality of connection nodes; and
a first dummy switching element coupled to the first output of the second switching network.

10. The offset cancellation circuit of claim 9, further including:
a second dummy switching element coupled to the second output of the second switching network;
a switching element having first and second terminals, the first terminal of the switching element coupled to the second switching network; and
a third dummy switching element coupled to the second terminal of the switching element.

11. The offset cancellation circuit of claim 9, further including an amplifier circuit having at least first and second inputs and first and second outputs, the first and second inputs of the amplifier circuit coupled to the first and second outputs of the first switching network, respectively, and the first and second outputs of the amplifier circuit coupled to the first and second inputs of the second switching network, respectively.

12. The offset cancellation circuit of claim 9, wherein the first switching network comprises:
a first switching element having first and second terminals;
a second switching element having first and second terminals, the second terminal of the second switching element coupled to the second terminal of the first switching element;
a third switching element having first and second terminals; and
a fourth switching element having first and second terminals, the second terminal of the fourth switching element coupled to the second terminal of the third switching element.

13. The offset cancellation network of claim 12, wherein the first terminals of the first, second, third, and fourth switching elements are coupled for receiving first, second, third, and fourth Hall element output voltages, respectively.

14. The offset cancellation network of claim 12, wherein the second switching network comprises:
a fifth switching element having first and second terminals, the first terminal of the fifth switching element coupled to the first terminal of the second capacitor at a first node;
a sixth switching element having first and second terminals, the second terminal of the sixth switching element coupled to the second terminal of the fifth switching element and second terminal of the sixth switching element coupled to the second terminal of the first capacitor at a third node;
a seventh switching element having first and second terminals, the first terminal of the seventh switching element coupled to the first terminal of the first capacitor at a second node; and
an eighth switching element having first and second terminals, the second terminal of the eighth switching element coupled to the second terminal of the seventh switching element and the second terminal of the eight switching element coupled to the second terminal of the second capacitor at a fourth node.

15. The offset cancellation network of claim 14, further including:
a ninth switching element having first and second terminals, the first terminal of the ninth switching element coupled to the first node; and
a tenth switching element having first and second terminals, the first terminal of the tenth switching element coupled to the second node, the second terminals of the ninth and tenth switching elements coupled together to form a fifth node.

16. The offset cancellation network of claim 15, further including
an eleventh switching element having first and second terminals, the first terminal of the eleventh switching element coupled to the fourth node; and
a twelfth switching element having first and second terminals, the first terminal of the twelfth switching element coupled to the third node, the second terminals of the eleventh and twelfth switching elements coupled together to form a sixth node.

17. The offset cancellation network of claim 16, wherein the first dummy switching element is coupled to the sixth node and further including a second dummy switching element coupled to the sixth node.

18. The offset cancellation network of claim 17, further including a
a thirteenth switching element having first and second terminals, the first terminal coupled to the fifth node; and
a third dummy switching element coupled to the second terminal of the thirteenth switching element.

19. A method for cancelling offset, comprising:
charging a first capacitor to a first voltage level;
charging channels of a plurality of dummy switching elements to a first charge level;
charging a second capacitor to a second voltage level;
charging the channels of the plurality of dummy switching elements to a second charge level; and
coupling the first and second capacitors in parallel with each other and redistributing the charge from the channels of the plurality of dummy switching elements to the first and second capacitors.

20. The method of claim 19, wherein charging the first capacitor comprises:
configuring a first plurality of switches to generate first and second voltages;
amplifying the first and second voltages to generate first and second amplified voltages; and
configuring a second plurality of switches to charge the first capacitor using the first and second amplified voltages.

21. The method of claim 20, wherein charging the second capacitor comprises:
configuring the first plurality of switches to generate third and fourth voltages;
amplifying the third and fourth voltages to generate third and fourth amplified voltages; and
configuring the second plurality of switches to charge the second capacitor using the third and fourth amplified voltages.

22. The method of claim 21, wherein charging the channels of a plurality of dummy switching elements to a first charge level and charging the plurality of dummy switching elements to the second voltage level comprises setting the plurality of dummy switching elements to an ON state.

23. The method of claim 21, wherein coupling the first and second capacitors in parallel with each other comprises closing a third plurality of switches.

24. The method of claim 21, wherein redistributing the charge from the channels of the plurality of dummy switching elements to the first and second capacitors comprises setting the plurality of dummy switching elements to an OFF state.

25. A method for cancelling offset, comprising:
providing a first switching network having a plurality of inputs and first and second outputs, wherein first, second, third, and fourth inputs of the plurality of inputs are coupled for receiving corresponding Hall element voltages;
providing a second switching network having first and second inputs and first and second outputs, the first and second inputs of the second switching network coupled to the first and second outputs of the first switching network;
providing a third switching network having first and second inputs and an output;
coupling a first capacitor between the first output of the second switching network and the first input of the third switching network;
coupling a second capacitor between the second output of the second switching network and the second input of the third switching network;
coupling a plurality of dummy switching elements to the third switching network; and
redistributing charge from the plurality of dummy switching elements to the third switching network.

26. The method of claim 25, wherein redistributing the charge from the plurality of dummy switching elements to the third switching network includes switching on the third switching network and switching off the plurality of dummy switching elements.

27. The method of claim 26, further including charging the first and second capacitors with the corresponding Hall element voltages.

28. The method of claim 25, wherein
charging the first capacitor comprises configuring the first switching network to be in a first state;
charging the second capacitor comprises configuring the second switching network to be in a second state; and
redistributing the charge from the plurality of dummy switches to the third switching network comprises configuring the third switching network to be in an output state.
